(19) United States
(12) Patent Application Publication
(10) Pub. No.: US 2023/0383406 A1
(43) Pub. Date: Nov. 30, 2023

(54) AXIALLY COOLED METAL SHOWERHEADS FOR HIGH TEMPERATURE PROCESSES

(71) Applicant: LAM RESEARCH CORPORATION, Fremont, CA (US)

(72) Inventors: Lipyeow YAP, San Jose, CA (US); Nivin VIKRAMAN, Bangalore (IN); Panya WONGSENAKHUM, Fremont, CA (US); Gary B. LIND, Penn Valley, CA (US)

(21) Appl. No.: 18/026,431

(22) PCT Filed: Jun. 2, 2021
(86) PCT No.: PCT/US2021/035377

§ 371 Date: Mar. 15, 2023

Related U.S. Application Data
(60) Provisional application No. 63/083,442, filed on Sep. 25, 2020.

(51) Int. Cl. C23C 16/455

(52) U.S. Cl. CPC C23C 16/45565

(57) ABSTRACT

A base portion of a showerhead is made of a first metallic material, has a first surface including a gas inlet and a second surface, and includes passages. A faceplate is made of a second metallic material and has side surfaces attached to the second surface and has a bottom surface that along with the second surface define a plenum. The faceplate includes walls that extend from the bottom surface upwards through the plenum and that contact the second surface, and outlets arranged along the walls. A heater is disposed in a groove along a periphery of the base portion. A cooling plate is arranged on the first surface and includes a conduit for a coolant. A plate is made of a third material having a lower thermal conductivity than the first and second metallic materials and is arranged between the cooling plate and the base portion.

### CROSS-REFERENCE TO RELATED APPLICATIONS

The present disclosure is a PCT International Application of U.S. Patent Application No. 63/083,442 filed on Sep. 25, 2020. The entire disclosure of the application referenced above is incorporated herein by reference.

### FIELD

The present disclosure relates generally to substrate processing systems and more particularly to axially-cooled metal showerheads for high temperature processes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Atomic Layer Deposition (ALD) is a thin-film deposition method that sequentially performs a gaseous chemical process to deposit a thin film on a surface of a material (e.g., a surface of a substrate such as a semiconductor wafer). Most ALD reactions use at least two chemicals called precursors (reactants) that react with the surface of the material one precursor at a time in a sequential, self-limiting manner. Through repeated exposure to separate precursors, a thin film is gradually deposited on the surface of the material.

Thermal ALD (T-ALD) is carried out in a heated processing chamber. The processing chamber is maintained at a sub-atmospheric pressure using a vacuum pump and a controlled flow of an inert gas. The substrate to be coated with an ALD film is placed in the processing chamber and is allowed to equilibrate with the temperature of the processing chamber before starting the ALD process.

### SUMMARY

A showerhead comprises a base portion, a faceplate, a heater, a cooling plate, and a metal plate. The base portion is made of a first metallic material, has a first surface including a gas inlet and a second surface opposite to the first surface, and includes a plurality of passages in fluid communication with the gas inlet. The faceplate is made of a second metallic material and has side surfaces attached to the second surface of the base portion and a bottom surface. The side surfaces and the bottom surface of the faceplate and the second surface of the base portion define a plenum that is in fluid communication with the plurality of passages. The faceplate includes a plurality of walls that extend from the bottom surface upwards through the plenum and that contact the second surface of the base portion. The bottom surface includes a plurality of outlets arranged along the walls in fluid communication with the plenum. The heater is disposed in a groove along a periphery of the base portion. The cooling plate is arranged on the first surface of the base portion and includes a conduit having an inlet to receive a coolant and an outlet. The metal plate is made of a third metallic material having a lower thermal conductivity than the first and second metallic materials and is arranged between the cooling plate and the base portion of the showerhead.

In other features, outer diameters of the cooling plate and the metal plate are less than or equal to an inner diameter of the groove.

In other features, the walls are vertical and concentric.

In another feature, the walls have different heights.

In another feature, the walls have different widths.

In other features, the walls and the outlets are arranged within a region of the faceplate, and outer diameters of the cooling plate and the metal plate are less than or equal to a diameter of the region.

In other features, the walls and the outlets are arranged within a region of the faceplate, and a diameter of the region is less than or equal to an inner diameter of the groove.

In other features, the cooling plate and the metal plate have smaller diameters than outer diameters than the base portion and the faceplate.

In other features, the first and second metallic materials are the same.

In other features, the base portion includes a flange extending radially outwards from a top end of the base portion, and the showerhead further comprises a clamping ring having a vertical portion arranged on the heater and having a horizontal portion attached to the flange.

In other features, the metal plate includes one or more recessed portions on at least one of top and bottom surfaces.

In another feature, the showerhead further comprises an additional plate made of a non-metal arranged between the metal plate and the base portion.

In another feature, the non-metal has a lower thermal conductivity than the third metallic material.

In another feature, an outer diameter of the additional plate is less than or equal to an outer diameter of the metal plate.

In another feature, the metal plate is thicker than the additional plate.

In another feature, the faceplate is diffusion bonded to the base portion.

In another feature, the base portion and the faceplate are coated with an anticorrosion material.

In other features, the metal plate comprises a first layer including one or more recessed portions, a second layer that is flat, and a third layer including one or more recessed portions.

In other features, the first, second, and third layers are diffusion bonded.

In other features, the recessed portions of the first and third layer are aligned with each other.

In other features, the recessed portions of the first and third layer partially overlap.

In other features, the recessed portions of the first and third layer do not overlap.

In other features, the base portion comprises first and second disc-shaped elements and a cylindrical element. The first disc-shaped element includes a groove proximate to an outer diameter of the first disc-shaped element. The heater is arranged in the groove. The second disc-shaped element is arranged on the first disc-shaped element and having an outer diameter that is less than or equal to an inner diameter of the groove. The cylindrical element is arranged on the first disc-shaped element and has an inner diameter that is greater than or equal to an outer diameter of the groove.

In other features, the first and second disc-shaped elements and the cylindrical element are diffusion bonded.

In another feature, the groove extends vertically from a top surface of the first disc-shaped element towards a bottom surface of the first disc-shaped element.

In other features, outer diameters of the first and second disc-shaped elements and a bottom portion of the cylindrical element are equal.

In other features, the first disc-shaped element comprises a slot at a center of a top surface of the first disc-shaped element. The slot is in fluid communication with the gas inlet and includes a plurality of grooves extending radially from the slot. The passages extend downward from distal ends of the grooves towards and through a bottom surface of the first disc-shaped element.

In other features, a top end of the cylindrical element includes a flange extending radially outwards, and the showerhead further comprises a clamping ring having a vertical portion arranged on the heater and having a horizontal portion attached to the flange.

In other features, the faceplate includes a plurality of grooves extending radially outwards from a center of the faceplate.

In other features, the grooves are of different lengths.

In other features, the walls are vertical and concentric, and the grooves intersect the walls.

In other features, the faceplate includes an annular recess along an outer diameter of the bottom surface, and the showerhead further comprises an edge ring disposed in the annular recess.

In other features, a processing chamber comprises the showerhead and a pedestal. The edge ring is proximate to an outer edge of a top surface of the pedestal.

In another feature, a radially outward gas flow through a gap between the edge ring and the outer edge of the top surface of the pedestal prevents contaminants from the processing chamber from flowing through the gap towards a substrate arranged on the pedestal during substrate processing.

In other features, a system comprises the showerhead, a gas distribution system to supply a process gas to the gas inlet, a fluid distribution system to supply a fluid to the conduit in the cooling plate, and a power supply to supply power to the heater.

In another feature, the system further comprises a controller to control the gas distribution system, the fluid distribution system, and the power supply.

In still other features, a showerhead comprises a base portion, a faceplate, a cooling plate, a first metal plate and a second plate. The base portion has a first surface including a gas inlet and a second surface opposite to the first surface. The base portion includes a plurality of passages in fluid communication with the gas inlet. The faceplate has side surfaces attached to the second surface of the base portion and a bottom surface including a plurality of outlets. The faceplate includes a plurality of walls extending upwards from the bottom surface upwards and contacting the second surface of the base portion. The cooling plate is arranged on the first surface of the base portion. The cooling plate includes a conduit having an inlet to receive a coolant and an outlet. The first metal plate is arranged between the cooling plate and the base portion of the showerhead. The first metal plate has a lower thermal conductivity than the faceplate and the cooling plate. The second plate is arranged between the first metal plate and the base portion. The second plate is made of a non-metal having a lower thermal conductivity than the first metal plate.

In another feature, the first metal plate comprises a first layer including one or more recessed portions, a second layer that is flat, and a third layer including one or more recessed portions.

In another feature, the base portion comprises a first disc-shaped element, a second disc-shaped element, and a cylindrical element. The first disc-shaped element includes a heater arranged in a groove proximate to an outer diameter of the first disc-shaped element. The second disc-shaped element is arranged on the first disc-shaped element and has an outer diameter that is less than or equal to an inner diameter of the groove. The cylindrical element is arranged on the first disc-shaped element and has an inner diameter that is greater than or equal to an outer diameter of the groove. Outer diameters of a bottom portion of the cylindrical element and the first and second disc-shaped elements are equal.

In other features, the first disc-shaped element comprises a slot at a center of a top surface of the first disc-shaped element. The slot is in fluid communication with the gas inlet and includes a plurality of grooves extending radially from the slot. The passages extend downward from distal ends of the grooves towards and through a bottom surface of the first disc-shaped element.

In other features, a top end of the cylindrical element includes a flange extending radially outwards. The showerhead further comprises a clamping ring having a vertical portion arranged on the heater and having a horizontal portion attached to the flange.

In other features, the faceplate includes a plurality of grooves extending radially outwards from a center of the faceplate. The grooves are of different lengths. The walls are vertical and concentric. The grooves intersect the walls. The faceplate includes an annular recess along an outer diameter of the bottom surface. The annular recess includes an edge ring allowing a radially outward gas flow through a gap between the edge ring and an outer edge of a top surface of a pedestal.

In still other features, a showerhead comprises a base portion, a faceplate, a heater, a cooling plate, and a plate. The base portion is made of a first metallic material. The base portion has a first surface including a gas inlet and a second surface opposite to the first surface. The base portion includes a plurality of passages in fluid communication with the gas inlet. The faceplate is made of a second metallic material. The faceplate has side surfaces attached to the second surface of the base portion and a bottom surface. The side surfaces and the bottom surface of the faceplate and the second surface of the base portion define a plenum in fluid communication with the plurality of passages. The faceplate includes a plurality of walls extending from the bottom surface upwards through the plenum and contacting the second surface of the base portion. The bottom surface includes a plurality of outlets arranged along the walls in fluid communication with the plenum. The heater is disposed in a groove along a periphery of the base portion. The cooling plate is arranged on the first surface of the base portion. The cooling plate includes a conduit having an inlet to receive a coolant and an outlet. The plate is made of a third material having a lower thermal conductivity than the first and second metallic materials. The plate is arranged between the cooling plate and the base portion of the showerhead.

In other features, outer diameters of the cooling plate and the plate are less than or equal to an inner diameter of the groove.

In other features, the walls are vertical and concentric. The walls have different heights. The walls have different widths.

In other features, the walls and the outlets are arranged within a region of the faceplate. Outer diameters of the cooling plate and the plate are less than or equal to a diameter of the region. The diameter of the region is less than or equal to an inner diameter of the groove.

In other features, the base portion includes a flange extending radially outwards from a top end of the base portion. The showerhead further comprises a clamping ring having a vertical portion arranged on the heater and having a horizontal portion attached to the flange.

In other features, the third material includes a thermoplastic material. The showerhead further comprises an additional plate arranged between the plate and the cooling plate. The additional plate has a different thermal conductivity than the third material.

In other features, a first outer diameter of the additional plate is greater than or equal to a second outer diameter of the plate. The plate is thinner than the additional plate.

In other features, the third material includes a thermoplastic material. The plate comprises a first layer including one or more recessed portions, a second layer that is flat, and a third layer including one or more recessed portions.

In other features, the recessed portions of the first and third layer are aligned with each other, the recessed portions of the first and third layer partially overlap, or the recessed portions of the first and third layer do not overlap.

In other features, the base portion comprises a first disc-shaped element, a second disc-shaped element, and a cylindrical element. The first disc-shaped element includes a groove proximate to an outer diameter of the first disc-shaped element. The heater is arranged in the groove. The second disc-shaped element is arranged on the first disc-shaped element and has an outer diameter that is less than or equal to an inner diameter of the groove. The cylindrical element is arranged on the first disc-shaped element and has an inner diameter that is greater than or equal to an outer diameter of the groove. Outer diameters of the first and second disc-shaped elements and a bottom portion of the cylindrical element are equal. The first and second disc-shaped elements and the cylindrical element are diffusion bonded.

In other features, the first disc-shaped element comprises a slot at a center of a top surface of the first disc-shaped element. The slot is in fluid communication with the gas inlet and includes a plurality of grooves extending radially from the slot. The passages extend downward from distal ends of the grooves towards and through a bottom surface of the first disc-shaped element.

In other features, a top end of the cylindrical element includes a flange extending radially outwards. The showerhead further comprises a clamping ring having a vertical portion arranged on the heater and having a horizontal portion attached to the flange.

In other features, the faceplate includes a plurality of grooves extending radially outwards from a center of the faceplate. The grooves are of different lengths. The walls are vertical and concentric. The grooves intersect the walls.

In other features, a processing chamber comprises the showerhead and a pedestal. The faceplate includes an annular recess along an outer diameter of the bottom surface. The showerhead includes an edge ring disposed in the annular recess. The edge ring is proximate to an outer edge of a top surface of the pedestal. A radially outward gas flow through a gap between the edge ring and the outer edge of the top surface of the pedestal prevents contaminants from the processing chamber from flowing through the gap towards a substrate arranged on the pedestal during substrate processing.

In still other features, a showerhead comprises a base portion, a faceplate, a cooling plate, and a plate. The base portion has a first surface including a gas inlet and a second surface opposite to the first surface. The base portion includes a plurality of passages in fluid communication with the gas inlet. The faceplate has side surfaces attached to the second surface of the base portion and a bottom surface including a plurality of outlets. The faceplate includes a plurality of walls extending upwards from the bottom surface upwards and contacting the second surface of the base portion. The cooling plate is arranged on the first surface of the base portion. The cooling plate includes a conduit having an inlet to receive a coolant and an outlet. The plate has a lower thermal conductivity than the faceplate and the cooling plate. The plate is arranged between the cooling plate and the base portion of the showerhead.

In other features, the plate is made of a thermoplastic material. The plate comprises a first layer including one or more recessed portions, a second layer that is flat, and a third layer including one or more recessed portions.

In other features, the base portion comprises a first disc-shaped element, a second disc-shaped element, and a cylindrical element. The first disc-shaped element includes a heater arranged in a groove proximate to an outer diameter of the first disc-shaped element. The second disc-shaped element is arranged on the first disc-shaped element and has an outer diameter that is less than or equal to an inner diameter of the groove. The cylindrical element is arranged on the first disc-shaped element and has an inner diameter that is greater than or equal to an outer diameter of the groove. Outer diameters of a bottom portion of the cylindrical element and the first and second disc-shaped elements are equal.

In other features, the first disc-shaped element comprises a slot at a center of a top surface of the first disc-shaped element. The slot is in fluid communication with the gas inlet and includes a plurality of grooves extending radially from the slot. The passages extend downward from distal ends of the grooves towards and through a bottom surface of the first disc-shaped element.

In other features, a top end of the cylindrical element includes a flange extending radially outwards. The showerhead further comprises a clamping ring having a vertical portion arranged on the heater and having a horizontal portion attached to the flange.

In other features, the faceplate includes a plurality of grooves extending radially outwards from a center of the faceplate. The grooves are of different lengths. The walls are vertical and concentric. The grooves intersect the walls. The faceplate includes an annular recess along an outer diameter of the bottom surface. The annular recess includes an edge ring allowing a radially outward gas flow through a gap between the edge ring and an outer edge of a top surface of a pedestal.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system that includes a processing chamber;

FIG. 2 shows an example of a showerhead;

FIG. 3 shows an example of a showerhead comprising a faceplate having a plurality of vertical walls;

FIG. 4 shows an example of a showerhead comprising a faceplate having a plurality of vertical walls and a heat choke;

FIG. 5 shows the showerhead of FIG. 4 with a pedestal;

FIG. 6 shows an example of the heat choke of the showerhead of FIG. 4;

FIG. 7 shows a top view of the showerhead of FIG. 4;

FIG. 8 shows a bottom view of the showerhead of FIG. 4;

FIGS. 9A and 9B show the showerhead of FIG. 4 in further detail;

FIGS. 10A and 10B isometric and side cross-sectional views of the showerhead of FIG. 4; and

FIGS. 11A and 11B show isometric and top cross-sectional views of the faceplate of the showerhead of FIG. 4.

In the drawings, reference numbers may be reused to identify similar and/or identical elements.

### DETAILED DESCRIPTION

Showerheads made of a metal such as aluminum are generally not used for processes performed at relatively high pedestal temperatures because processes requiring pedestal temperatures of about 575 to 650 degrees Celsius result in a relatively large heat flow to the showerhead. The heat flow to the showerhead is typically balanced by heat flux direction driven radially from center regions to edge regions of the showerhead. In the edge regions of the showerhead, thermal coupling is made to a colder top plate or sidewall of the processing chamber. The thermal coupling causes a temperature gradient (e.g., of about 80 to 120 degrees Celsius) in metal showerheads. The temperature gradient in turn causes a relatively large temperature gradient in substrates during processing due to the thermal coupling between the showerhead and the substrate, particularly when the gap between the showerhead and the substrate is relatively small (e.g., in processes such as ALD).

In the present disclosure, heat flow paths through vertical plenum walls in the showerhead enhance axial heat flow from bottom to top of the showerhead, which in turn reduces a radial temperature gradient across the showerhead. Specifically, instead of using an open plenum with a cavity in the center of the showerhead, the showerhead according to the present disclosure uses spoke-like grooves in the faceplate of the showerhead (shown and described below in detail) to distribute gas flow within the showerhead. The spoke-like grooves allow inclusion of vertical walls in the plenum of the showerhead that serve a dual purpose. In addition to distributing gas flow within the showerhead, these walls also provide heat flow paths from bottom to top of the showerhead. The resulting axial heat flow paths and axial temperature gradient in the showerhead significantly reduce a radial temperature range across a faceplate of the showerhead (e.g., from about 150 degrees Celsius to about 30 degrees Celsius in some processes).

For additional thermal management, a combination of heating, cooling, and a heat choke (explained below) is used in the showerhead according to the present disclosure. The cooling plate is arranged on a top surface of the showerhead and is designed to cool a center region of the showerhead while keeping heating capacity at the edge of the showerhead for temperature control. A heater coil is disposed along the periphery of the showerhead. The heat choke is arranged between the cooling plate and the faceplate of the showerhead as described below.

Due to the heating, cooling, and the heat choke, the showerhead can be used in processes performed at temperatures as high as 650 degrees Celsius with relatively small gaps between the showerhead and the pedestal while keeping the showerhead relatively cool (e.g., at temperatures below 200 degrees Celsius). Keeping the showerhead cool preserves a corrosion resistant coating applied to the showerhead. Due to the thermal management provided by the heating, cooling, and the heat choke, the showerhead is not damaged due to heat load from the pedestal while operating at such reduced gaps.

Additionally, by reducing the gap between the showerhead and the pedestal, the volume of gases flowing through the showerhead can be significantly reduced due to the grooves and walls used for gas distribution in the showerhead instead of using a plenum with a cavity in the showerhead. The reduction in flow volume helps reduce precursor consumption in processes, which reduces cost. Due to the reduction in flow volume, process gases can be purged rapidly, which reduces time durations between gas transitions, which in turn reduces cycle times in processes such as ALD. Due to reduced cycle times, more number of substrates can be processed in the same amount of time, which increases throughput. These and other features of the showerhead according to the present disclosure are described below in detail.

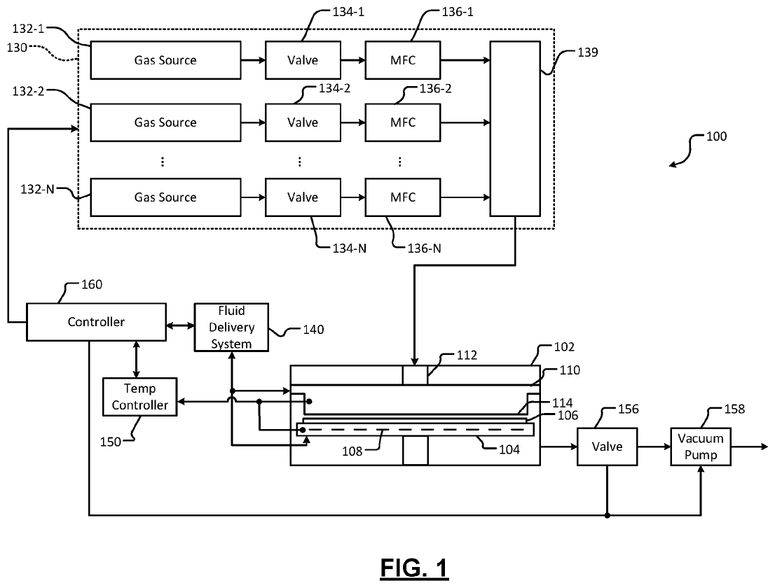

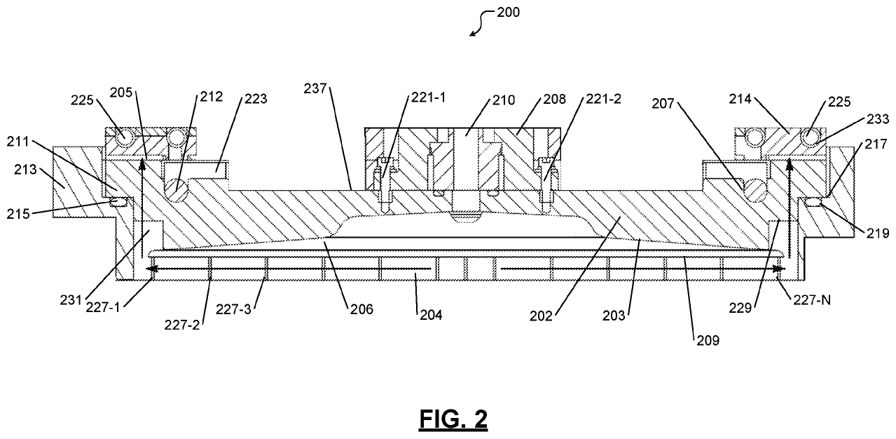

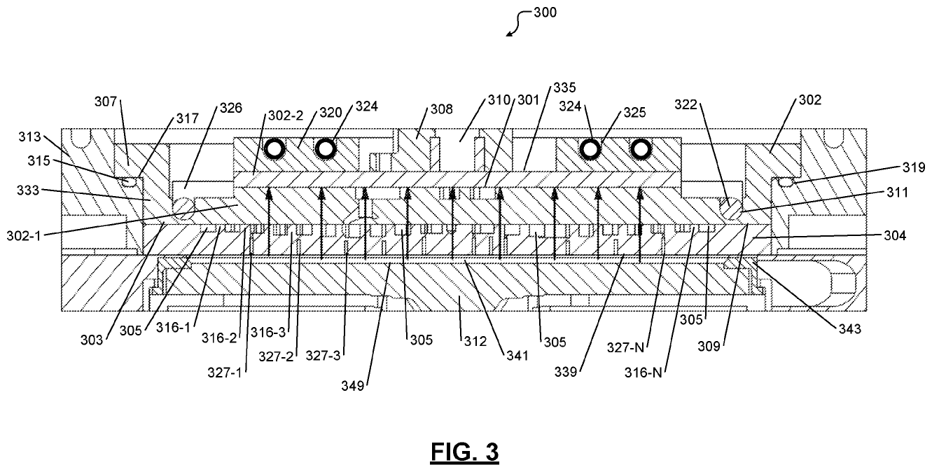

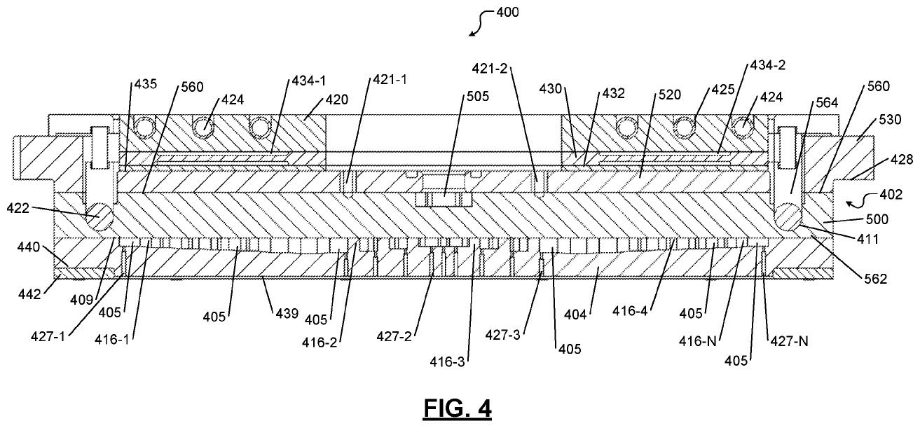

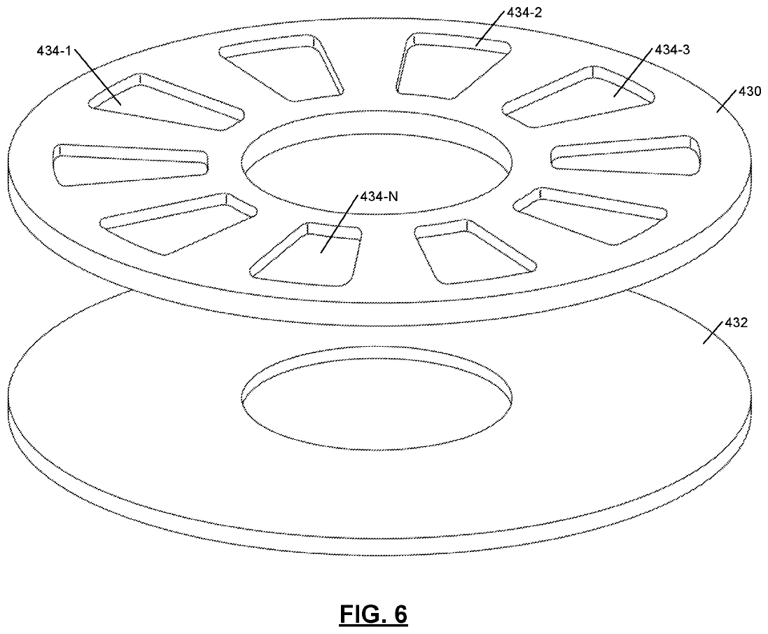

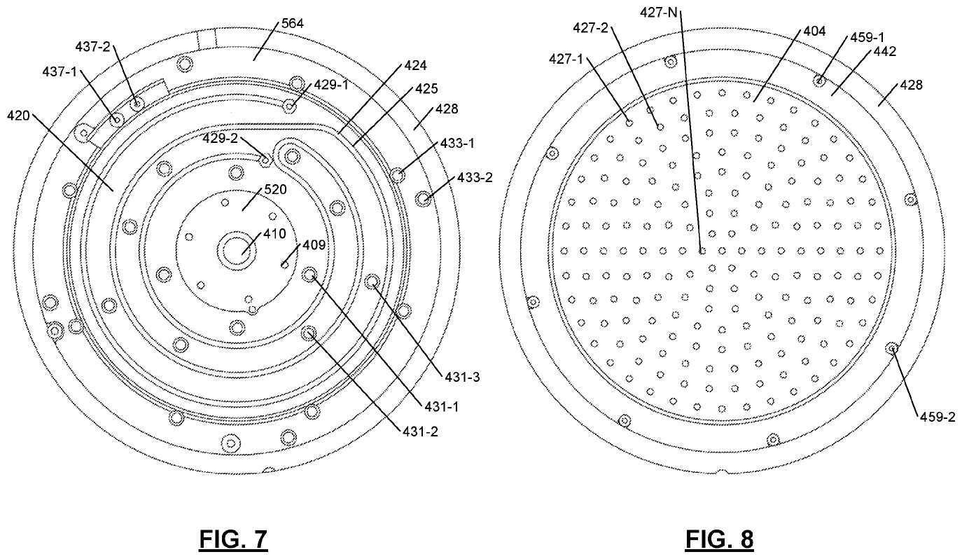

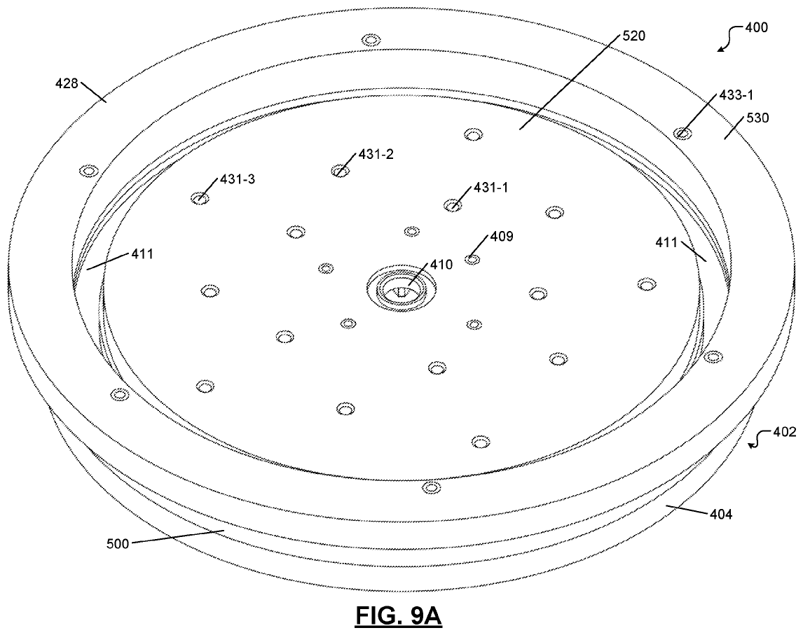

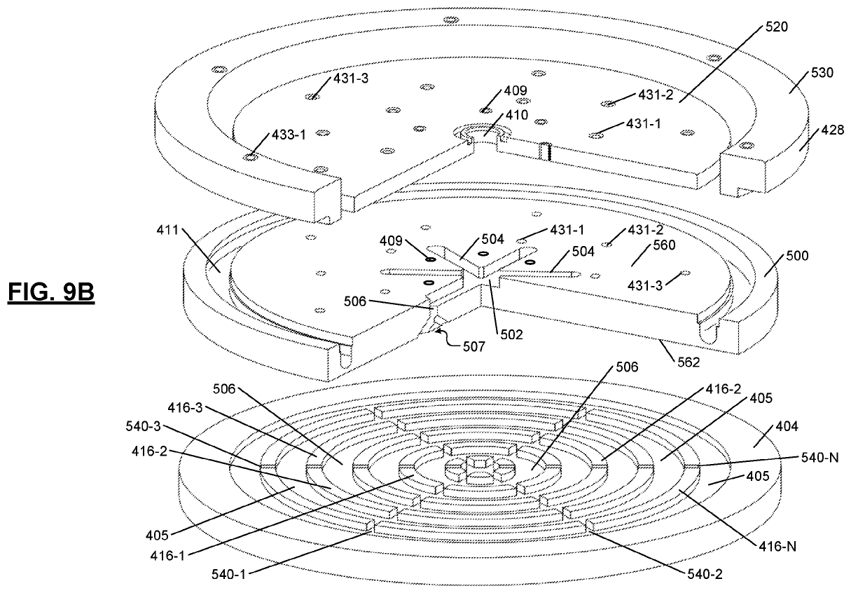

The present disclosure is organized as follows. An example of a processing chamber in which a showerhead according to the present disclosure can be used is shown and described with reference to FIG. 1. The problems solved by the showerhead of the present disclosure are described with reference to FIG. 2. Examples of showerheads according to the present disclosure that solve the problems are shown and described with reference to FIGS. 3-5. Examples of heat chokes used in the showerhead of FIG. 4 are shown and described with reference to FIG. 6. Top and bottom views of the showerhead of FIG. 4 are shown and described with reference to FIGS. 7 and 8, respectively. The showerhead of FIG. 4 is shown and described in further detail with reference to FIGS. 9A-11B.

FIG. 1 shows an example of a substrate processing system 100 comprising a processing chamber 102 configured to process a substrate using thermal atomic layer deposition (T-ALD). The processing chamber 102 encloses other components of the substrate processing system 100. The processing chamber 102 comprises a substrate support (e.g., a pedestal) 104. During processing, a substrate 106 is arranged on the pedestal 104.

One or more heaters 108 (e.g., a heater array) may be disposed in a ceramic plate arranged on a metallic baseplate of the pedestal 104 to heat the substrate 106 during processing. One or more additional heaters called zone heaters or primary heaters (not shown) may be arranged in the ceramic plate above or below the heaters 108. Additionally, while not shown, a cooling system comprising cooling channels through which a coolant can flow to cool the pedestal 104 may be disposed in the baseplate of the pedestal 104; and one or more temperature sensors may be disposed in the pedestal 104 to sense the temperature of the pedestal 104.

The processing chamber 102 comprises a gas distribution device 110 such as a showerhead to introduce and distribute process gases into the processing chamber 102. The gas distribution device (hereinafter showerhead) 110 is made of a metal such as aluminum or an alloy. The showerhead 110 may include a stem portion 112 including one end connected to a top surface of the processing chamber 102. A base portion 114 of the showerhead 110 is generally cylindrical and extends radially outwardly from an opposite end of the stem portion 112 at a location that is spaced from the top surface of the processing chamber 102.

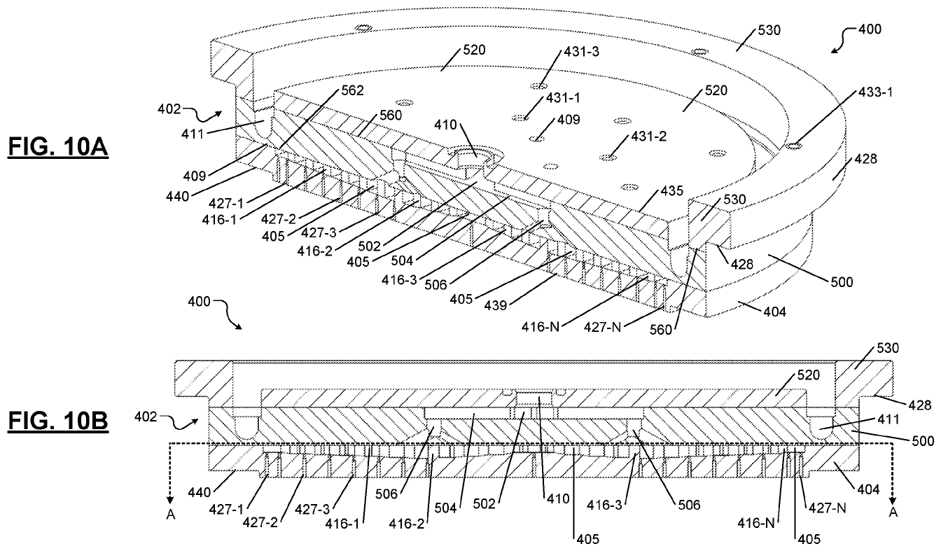

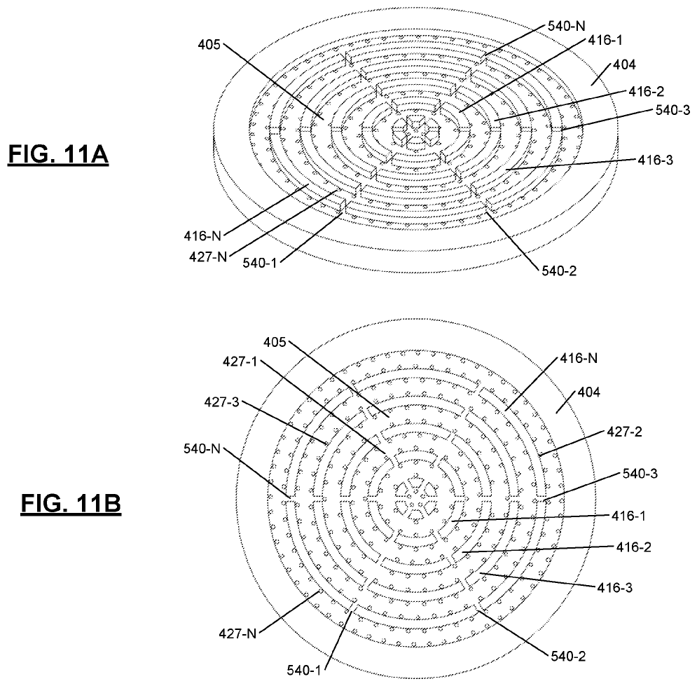

A substrate-facing surface of the base portion 114 of the showerhead 110 comprises a faceplate (shown in subsequent figures). The faceplate comprises a plurality of outlets or features (e.g., slots or through holes) through which precursors flow into the processing chamber 102. The faceplate of the showerhead 110 is shown and described in detail with reference to FIGS. 10A-11B.

The showerhead 110 also comprises a cooling plate and a heater (shown and described with reference to subsequent figures). The cooling plate includes a conduit (see FIG. 7) through which a coolant can be circulated as described below. Additionally, while not shown, one or more temperature sensors may be disposed in the showerhead 110 to sense the temperature of the showerhead 110. The showerhead 110 comprises additional features such as one or more heat chokes and an edge ring, which are shown and described below in detail with reference to subsequent figures.

A gas delivery system 130 comprises one or more gas sources 132-1, 132-2, . . . , and 132-N (collectively, the gas sources 132), where N is an integer greater than zero. The gas sources 132 are connected by valves 134-1, 134-2, . . . , and 134-N (collectively, the valves 134) and mass flow controllers 136-1, 136-2, . . . , and 136-N (collectively, the mass flow controllers 136) to a manifold 139. An output of the manifold 139 is fed to the processing chamber 102. The gas sources 132 may supply process gases, cleaning gases, purge gases, inert gases, and so on to the processing chamber 102.

A fluid delivery system 140 supplies a coolant to the cooling system in the pedestal 104 and to the cooling plate in the showerhead 110. A temperature controller 150 may be connected to the heaters 108, the zone heaters, the cooling system, and the temperature sensors in the pedestal 104. The temperature controller 150 may also be connected to the cooling plate, the heater, and the temperature sensors in the showerhead 110. The temperature controller 150 may control power supplied to the heaters 108, the zone heaters, and coolant flow through the cooling system in the pedestal 104 to control the temperature of the pedestal 104 and the substrate 106. The temperature controller 150 may also control power supplied to the heater disposed in the showerhead 110 and coolant flow through the conduit disposed in the cooling plate of the showerhead 110 to control the temperature of the showerhead 110.

A vacuum pump 158 maintains sub-atmospheric pressure inside the processing chamber 102 during substrate processing. A valve 156 is connected to an exhaust port of the processing chamber 102. The valve 156 and the vacuum pump 158 are used to control pressure in the processing chamber 102 and to evacuate reactants from the processing chamber 102 via the valve 156. A system controller 160 controls the components of the substrate processing system 100.

FIG. 2 shows a showerhead 200 comprising a base portion 202 and a faceplate 204 that is attached to the base portion 202 with a spatial offset from a bottom surface 203 of the base portion 202. The showerhead 200 (i.e., both the base portion 202 and the faceplate 204) is made of a metal such as aluminum or an alloy. In some examples, the base portion 202 and the faceplate 204 may be made of different metals or alloys.

The bottom surface 203 of the base portion 202 is non-planar. For example, the bottom surface 203 of the base portion 202 is substantially concave. A top surface 209 of the faceplate 204 is planar. The bottom surface 203 of the base portion 202 and the top surface 209 of the faceplate 204 define a plenum 206.

A top surface 205 of the base portion 202 is substantially planar. The top surface 205 includes a groove 207 proximate to an outer diameter (OD) of the top surface 205. A heater coil 212 is mounted in the groove 207 using a flat ring 223. The flat ring 223 is coplanar with the top surface 205 of the base portion 202 and extends radially inwardly from an outer edge of the groove 207 towards the center of the base portion 202. The top surface 205 extends radially outwards from the OD of the groove 207 towards the OD of the top surface 205, then vertically downwards, and then radially inwards towards the center of the base portion 202 to form a first flange 211.

A top plate 213 of a processing chamber surrounds the base portion 202 and the faceplate 204 of the showerhead 200. The top plate 213 includes a flange 217 that extends radially inwards from an inner diameter (ID) of the top plate 213. The first flange 211 of the base portion 202 overhangs the flange 217 of the top plate 213. An O-ring 215 is disposed in a groove 219 in the flange 217.

The base portion 202 extends vertically upwards from the bottom surface 203 at the OD of the base portion 202, then extends radially outwards, and then vertically upwards to the bottom of the first flange 211, forming a second flange 229. The second flange 229 has a smaller diameter than the first flange 211. A peripheral portion 231 of the faceplate 204 extends vertically upwards from an OD of the faceplate 204 to the second flange 229. The faceplate 204 is attached to the base portion 202 at the second flange 229.

The showerhead 200 has a stem portion 208. One end of the stem portion 208 is attached to the top of the processing chamber. The other end of the stem portion 208 is attached to the center of the top region 237 of the base portion 202 using fasteners 221-1, 221-2. The stem portion 208 includes an inlet 210 to receive one or more gases from a gas delivery system. The inlet 210 extends vertically downwards through the stem portion 208, through the center of the base portion 202, into the plenum 206. The gases flow from the inlet 210 into the plenum 206, and then through a plurality of holes 227-1, 227-2, 227-3, . . . , and 227-N, where N is an integer greater than 1, (collectively, the through holes 227) into the processing chamber.

A cooling plate 214 is arranged above the base portion 202. The cooling plate 214 is annular with an OD substantially equal to the OD of the base portion 202. An ID of the cooling plate 214 is substantially equal to an ID of the groove 207. The cooling plate 214 includes a conduit 225 through which a coolant from a fluid delivery system flows. The conduit 225 is disposed in a groove 233 in the cooling plate 214. The cooling plate 214 provides cooling at the edge of the base portion 202.

When used in close proximity to a pedestal in processes requiring relatively high temperatures (e.g., ALD), the faceplate 204 of the showerhead 200 has a relatively large radial temperature gradient. For example, heat flows from the center of the faceplate 204 towards the OD of the faceplate 204 and upwards towards the cooling plate 214 along paths shown by arrows. For example, in some processes, the temperature at the center of the faceplate 204 can be about 330 degrees Celsius while the temperature at the edge of the faceplate 204 can be about 190 degrees Celsius (due to heat loss to the relatively colder top plate 213 of the processing chamber), which results in a radial temperature gradient across the faceplate 204 of about 140 degrees Celsius.

FIG. 3 shows a showerhead 300 arranged in close proximity to a pedestal 312 according to the present disclosure. The showerhead 300 includes a base portion 302 and a faceplate 304. The showerhead 300 (i.e., both the base portion 302 and the faceplate 304) is made of a metal such as aluminum or an alloy, diffusion bonded together. In some examples, the base portion 302 and the faceplate 304 may be made of different metals or alloys.

The base portion 302 comprises two elements: 302-1 and 302-2 (collectively, the base portion 302), diffusion bonded together. The first element 302-1 is cylindrical. A peripheral portion 333 of the first element 302-1 extends vertically upwards and then radially outwards to form a flange 307 along an OD of the first element 302-1. A top surface 301 of the first element 302-1 is substantially planar and includes a groove 311. The groove 311 is located proximate to the peripheral portion 333 of the first element 302-1. A heater coil 322 is mounted in the groove 311 using a flat ring 326. The flat ring 326 extends radially inwardly from an outer edge of the groove 311 towards the center of the first element 302-1. The second element 302-2 of the base portion 302 is a flat disc-shaped element that is attached to the top surface 309 of the first element 302-1. The second element 302-2 has an OD that is equal to an ID of the flat ring 326.

The showerhead 300 differs from the showerhead 200 shown in FIG. 2 in many respects. First, the structure of base portion 302 and the faceplate 304 of the showerhead 300 is different than the structure of the base portion 202 and the faceplate 204 of the showerhead 200 shown in FIG. 2. Specifically, while the bottom surface 203 of the base portion 202 of the showerhead 200 is non-planar and at a spatial offset from the faceplate 204, a bottom surface 303 of the base portion 302 of the showerhead 300 is planar.

Second, the bottom surface 303 of the base portion 302 is in direct contact with a top surface 309 of the faceplate 304, which is also planar. The base portion 302 and the faceplate 304 define a plenum 305 that is unlike the plenum 206 of the showerhead 200. The plenum 305 of the showerhead 300 differs from the plenum 206 of the showerhead 300 because unlike the faceplate 204 of the showerhead 200, the faceplate 304 of the showerhead 300 includes a plurality of vertical walls 316-1, 316-2, 316-3, . . . , and 316-N, where N is an integer greater than 1 (collectively, the vertical walls 316). The vertical walls 316, which extend through the plenum 305 from the faceplate 304 to the base portion 302, are absent in the plenum 206 of the showerhead 200.

The vertical walls 316 may have a uniform height or may have different heights. The vertical walls 316 may have uniform width of may have different widths. Since the vertical walls 316 extend from the bottom of the faceplate 304 to the top surface 309 of the faceplate 304 and contact the bottom surface 303 of the base portion 302, the vertical walls 316 provide heat flow paths from the bottom of the faceplate 304 to the base portion 302 along a vertical axis of the showerhead 300. Accordingly, the vertical walls 316 provide axial cooling of the showerhead 300. These heat flow paths and the axial cooling provided by the vertical walls 316 are absent in the showerhead 200. The axial cooling provided by the vertical walls 316 helps reduce a radial temperature gradient across the faceplate 304 of the showerhead 300.

Third, the showerhead 300 comprises a cooling plate 320 that is different than the cooling plate 214 of the showerhead. Specifically, unlike the cooling plate 214 which is annular and provides cooling only at the edge of the showerhead 200, the cooling plate 320 is larger in size (larger surface area in contact with showerhead) than the cooling plate 214 and extends from the center (specifically from a stem portion described below) of the showerhead 300 to the OD of the second element 302-2 of the base portion 302 of the showerhead 300.

The cooling plate 320 is disposed on top of, and is attached to, the second element 302-2 of the base portion 302. The cooling plate 320 includes a conduit 324 through which a coolant from a fluid delivery system flows. The conduit 324 is disposed in a groove 325 in the cooling plate 320. Heat flows from the bottom of the faceplate 304, via the vertical walls 316, through the first and second elements 302-1, 302-2 of the base portion 302, to the cooling plate 320, as shown by vertical arrows. Accordingly, unlike the cooling plate 214, which cools the edge of the showerhead 200, the cooling plate 320 cools the center region of the showerhead 300.

A top plate 313 of a processing chamber surrounds the base portion 302 and the faceplate 304 of the showerhead 300. The top plate 313 includes a flange 317 that extends radially inwards from an inner diameter (ID) of the top plate 313. The flange 307 of the base portion 302 overhangs the flange 317 of the top plate 313. An O-ring 315 is disposed in a groove 319 in the flange 317.

The showerhead 300 has a stem portion 308. One end of the stem portion 308 is attached to the top of the processing chamber. The other end of the stem portion 308 is attached to the center of a top surface 335 of the second element 302-2 of the base portion 302. The stem portion 308 includes an inlet 310 to receive one or more gases from a gas delivery system.

The inlet 310 extends vertically downwards through the stem portion 308 and connects to the plenum 305 via a slot (an example is shown in FIGS. 9A-10B) in the center of the base portion 302. A bottom surface 339 of the faceplate 304 includes a plurality of holes 327-1, 327-2, 327-3, . . . , and 327-N, where N is an integer greater than 1 (collectively, the through holes 327). The gases flow from the inlet 310 through the slot into the plenum 305, and then through the plurality of holes 327 at the bottom surface 339 of the faceplate 304 into the processing chamber. The bottom surface 339 of the faceplate 304 is in close proximity to a top surface 349 of the pedestal 312 arranged in the processing chamber.

During processing, a substrate 341 is arranged on the pedestal 312. The pedestal includes a ring 343 that surrounds the top surface 349 of the pedestal 312 to support the substrate 341. While not shown, the pedestal 312 includes other features of the substrate support 110 described with reference to FIG. 1.

The axial cooling of the showerhead 300 provided by the vertical walls 316 in the faceplate 304 can be enhanced and the radial temperature gradient across the showerhead 300 can be further reduced by increasing the diameter of the cooling plate 320 and arranging the heater coil 322 differently as explained below. A heat choke can be added to further enhance the thermal management and to further improve the axial cooling and the radial temperature gradient across the showerhead as explained below.

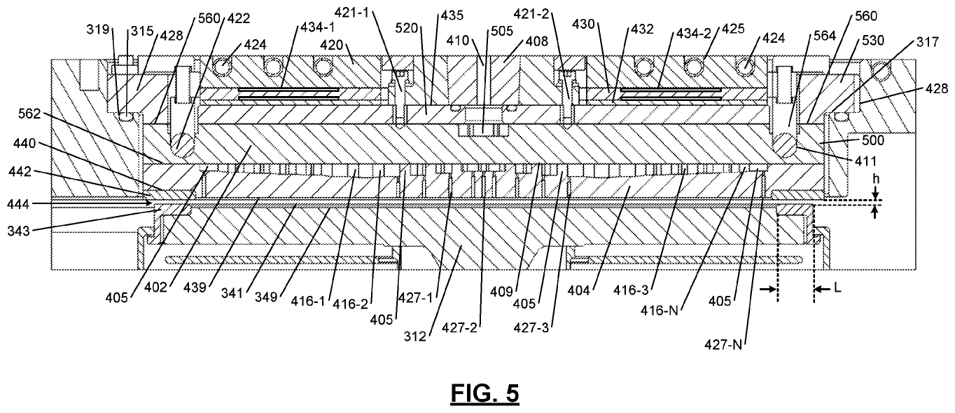

FIGS. 4 and 5 show a showerhead 400 according to the present disclosure. FIG. 4 shows the showerhead 400, and FIG. 5 shows the showerhead 400 arranged on the pedestal 312 according to the present disclosure. The showerhead 400 includes a base portion 402, a faceplate 404, and a flange portion 530. The showerhead 400 (i.e., the base portion 402, the faceplate 404, and the flange portion 530) is made of a metal such as aluminum or an alloy, diffusion bonded together. In some examples, the base portion 402 and the faceplate 404 may be made of different metals or alloys.

The showerhead 400 differs from the showerhead 300 in many respects. In addition to using a larger cooling plate and a different arrangement of a heater coil than the showerhead 300, the showerhead 400 additionally includes a heat choke that is absent in the showerhead 300. These elements of the showerhead 400 are described below in detail.

The base portion 402 and the faceplate 404 are shown and described in further detail with reference to FIGS. 9A-11B. Briefly, the base portion 402 comprises three components: a first component 500, a second component 520, and a third component 530, which are collectively called the base portion 402. The first component 500 is a disc-shaped element with planar top and bottom surfaces 560, 562. The second component 520 is a flat disc-shaped element that is attached to the top surface 560 of the first component 500.

The third component 530 (called the flange portion 530 above since it includes a flange 428 described below) is a cylindrical element that is attached to the first component 500 at an OD of the first component 500. An OD of a bottom portion of the third component 530 that is attached to the first component 500 is equal to the OD of the first component 500. The third component 530 extends vertically from the OD of the first component 500 and then extends radially outwards to form a flange 428.

The top surface 560 of the first component 500 includes a groove 411 proximate to the OD of the first component 500. A heater coil 422 is mounted in the groove 411 using a clamping ring 564 having an inverted L shape. The clamping ring 564 extends vertically upwards from the top of the heater coil 422 and then extends radially outwards forming the inverted L shape and is attached to the flange 428. The base portion 402 is shown and described below in further detail with reference to FIGS. 9A and 9B.

The showerhead 400 differs from the showerhead 300 shown in FIG. 3 in many respects. First, unlike the flat ring 326 used to mount the heater coil 322 in the showerhead 300, which extends radially inwards, the inverted L shaped clamping ring 564 used to mount the heater coil 422 in the showerhead 400 extends vertically up and then radially outwards. This inverted L shape of the clamping ring 564 allows using a cooling plate 420 of a greater diameter than the cooling plate 320 used in the showerhead 300. An OD of the cooling plate 420 is less than or equal to an ID of the groove 411 in which the heater coil 422 is disposed. The increased size (diameter) of the cooling plate 420 increases the axial cooling along a vertical axis of the showerhead 400 as compared to the axial cooling provided by the cooling plate 320 for the showerhead 300. The increased axial cooling provided by the cooling plate 420 in turn further reduces the radial temperature gradient across the faceplate 404 of the showerhead 400.

Second, unlike the showerhead 300, the showerhead 400 includes a thermal resistor formed by first and second plates 430, 432 each having a lower thermal conductivity than the metal(s) or alloy(s) used for the base portion 402 and the faceplate 404. The first and second plates 430, 432 impede the heat flow (i.e., make the heat flow gradual) from the faceplate 404 to the cooling plate 420 to prevent a coolant in the cooling plate 420 from boiling as explained below in further detail. Additionally, the first plate 430 includes a plurality of recessed portions 434-1, 432-2 (collectively, the recessed portions 434, shown in detail in FIG. 6) that further increase impedance of the thermal resistor formed by the first and second plats 430, 432 as described below in further detail with reference to FIG. 6.

The combination of the cooling plate 420, the heater coil 422, and the first and second plates 430, 432 significantly improves thermal management in the showerhead 400 by balancing heating and cooling of the showerhead 400 as compared to the showerhead 300. The improved thermal management reduces the radial temperature gradient across the faceplate 404 of the showerhead 400. The reduced thermal stresses on the showerhead 400 allow the showerhead 400 to be placed closer to the pedestal 312 than the showerhead 300.

The smaller gap between the faceplate 404 and the pedestal 312 allows reducing the flow volume of process gases, which reduces cost. Reducing the flow volume of process gases makes process cycles faster because smaller amounts of process gases can be rapidly purged, and transition between process gases during process cycles can be performed faster. This in turn makes it possible to process more number of substrates in the same amount of time, resulting in higher throughput.

More specifically, the bottom surface 562 of the base portion 402, which is planar, is in direct contact with a top surface 409 of the faceplate 404, which is also planar. The base portion 402 and the faceplate 404 define a plenum 405. The faceplate 404 of the showerhead 400 includes a plurality of vertical walls 416-1, 416-2, 416-3, . . . , and 416-N, where N is an integer greater than 1 (collectively, the vertical walls 416). The vertical walls 416 extend through the plenum 405 from the faceplate 404 to the base portion 402 and contact the base portion 402.

Since the vertical walls 416 extend from the bottom of the faceplate 404 to the top surface 409 of the faceplate 404 and contact the bottom surface 562 of the base portion 402, the vertical walls 416 provide heat flow paths from the bottom of the faceplate 404 to the base portion 402 along a vertical axis of the showerhead 400. Accordingly, the vertical walls 416 provide axial cooling of the showerhead 400. The axial cooling provided by the vertical walls 416 helps reduce a radial temperature gradient across the faceplate 404 of the showerhead 400 (e.g., from about 150 degrees Celsius to about 30 degrees Celsius in some processes). The vertical walls 416 may have a uniform height or may have different heights. The vertical walls 416 may have uniform width of may have different widths. The vertical walls 416 are shown and described in further detail with reference to FIGS. 10A-11B.

The cooling plate 420 extends from the center (specifically from a stem portion described below) of the showerhead 400 to the OD of the second component 520 of the base portion 402 of the showerhead 400. The cooling plate 420 is disposed on top of, and is attached to, the first and second plates 430, 432. The cooling plate 420 includes a conduit 424 through which a coolant from a fluid delivery system flows. The conduit 424 is disposed in a groove 425 in the cooling plate 420. Heat flows from the bottom of the faceplate 404, via the vertical walls 416, through the base portion 402 and the first and second plates 430, 432, to the cooling plate 420.

Since the cooling plate 420 of the showerhead 400 is greater in diameter than the cooling plate 320 of the showerhead 300, the cooling plate 420 covers and cools a greater area of the base portion 402 than the area of the base portion 302 covered and cooled by the cooling plate 320 of the showerhead 300. Specifically, the cooling plate 420 cools most of the portion of the showerhead 400 extending from the center of the showerhead 400 up to the heater coil 422. Accordingly, the cooling plate 420 significantly improves the axial cooling across the showerhead 400 as compared to the axial cooling provided by the cooling plate 320 in the showerhead 300.

In FIG. 5, the showerhead 400 has a stem portion 408. One end of the stem portion 408 is attached to the top of a processing chamber. The other end of the stem portion 408 is attached, through the first and second plates 430, 432, to the center of a top surface 435 of the second component 520 of the base portion 402 using fasteners 421-1, 421-2. The stem portion 308 includes an inlet 410 to receive one or more gases from a gas delivery system.

The inlet 410 extends vertically downwards through the stem portion 408, through the first and second plates 430, 432 and base portion 402, and connects to the plenum 405 via a slot 502 (shown and described in further detail in FIGS. 9A-11B) in the center of first component 500 of the base portion 402. A bottom surface 439 of the faceplate 404 includes a plurality of through holes 427-1, 427-2, 427-3, . . . , and 427-N, where N is an integer greater than 1 (collectively, the through holes 427). The gases flow from the inlet 410 through the slot 502 into the plenum 405, and then via the plurality of through holes 427 at the bottom surface 439 of the faceplate 404 into the processing chamber. The bottom surface 439 of the faceplate 404 is in close proximity to the top surface 349 of the pedestal 312 arranged in the processing chamber.

During processing, the substrate 341 is arranged on the pedestal 312. The pedestal 312 includes the ring 343 that surrounds top surface 349 of the pedestal 312 to support the substrate 341. While not shown, the pedestal 312 includes other features of the substrate support 110 described with reference to FIG. 1.

The top plate 313 of the processing chamber surrounds the base portion 402 and the faceplate 404 of the showerhead 400. The top plate 313 includes the flange 317 that extends radially inwards from the ID of the top plate 313. The flange 428 of the base portion 402 overhangs the flange 317 of the top plate 313. The O-ring 315 is disposed in the groove 319 in the flange 317.

The top plate 313 of the processing chamber is colder than the showerhead 400. As a result, while the center region of the faceplate 404 is relatively hot due to heat load from the pedestal 312, the edge of the showerhead 400 loses heat to the top plate 313 of the processing chamber. The heater coil 422 helps offset the heat loss along the edge of the showerhead 400, and the cooling plate 420 cools the center region of the showerhead 400. The combination of the heating and cooling reduces the radial temperature gradient from the center to the OD of the showerhead 400.

The showerhead 400, specifically the base portion 402 and the faceplate 404, are coated with an anticorrosion material such as nickel. The emissivity of the anticorrosion material further reduces the temperature gradient across the showerhead 400. The coating, however, can degrade (e.g., crystallize) above a threshold temperature (e.g., about 200 degrees Celsius for nickel coating). To prevent the coating from degrading, the cooling plate 420 keeps the temperature of the showerhead 400 below the threshold temperature.

However, while the cooling plate 420 keeps the temperature of the showerhead 400 below the threshold temperature, coolant flowing through the conduit 424 can become hot as heat flows from the faceplate 404 to the cooling plate 420 and can lose the ability to provide cooling (i.e., cooling capacity). For example, if water is used as the coolant (although other coolants can be used), the water can boil at 100 degrees Celsius and lose cooling capacity. Since the temperature of the showerhead 400 can reach about 200 degrees Celsius, the temperature of the coolant needs to be kept well below a boiling point of the coolant (e.g., well below 100 degrees Celsius if water is used as coolant). This is accomplished by using the thermal resistor (also called a heat choke) comprising the first and second plates 430, 432 that is interposed between the faceplate 404 and the cooling plate 420 to impede heat flow from the faceplate 404 to the cooling plate 420 and to prevent the coolant from overheating and boiling.

Specifically, the showerhead 400 comprises the first plate 430 and the second plate 432 that are disposed between the cooling plate 420 and the base portion 402 (more specifically disposed between the cooling plate 320 and the second component 520 of the base portion 402) as shown. The first and second plates 430, 432, which form the thermal resistor (or heat choke), are shown and described below in further detail with reference to FIG. 6. Briefly, the first and second plates 430, 432 are made of materials having different thermal conductivities, each of which is less than the thermal conductivity of the metal(s) or alloy(s) of which the base portion 402 and the faceplate 404 are made. For example, if the base portion 402 and the faceplate 404 are made of aluminum, the first plate 430 can be made of stainless steel, and the second plate 432 can be made of a non-metal (e.g., a semiconductor material). For example, the thermal conductivity of the first plate 430 is less than that of the base portion 402 and the faceplate 404 and greater than that of the second plate 432.

Accordingly, the first and second plates 430, 432 form the thermal resistor that gradually impedes heat flow (i.e., makes the heat flow gradual) from the faceplate 404 to the cooling plate 420 to prevent overheating of the coolant in the conduit 424. Specifically, the thermal resistor prevents the coolant from reaching its boiling point. The first plate 430 additionally includes the recessed portions 434, which provide air pockets that further increase the thermal resistance of the thermal resistor.

The showerhead 400 provides many advantages over showerheads comprising a ceramic faceplate. Specifically, the showerhead 400, being made of one or more metals or alloys, has a higher thermal conductivity than showerheads comprising a ceramic faceplate. For example, the thermal conductivity of aluminum is about 5× to 6× higher than that of a ceramic material. The higher conductivity of the showerhead 400 reduces the temperature gradient across the showerhead 400. Further, while thermal stresses can damage (e.g., fracture) the ceramic faceplate, the thermal stresses do not cause such catastrophic failures in the showerhead 400. Accordingly, the showerhead 400 can be arranged closer to the pedestal 312 (see FIG. 5) than showerheads comprising a ceramic faceplate.

In addition, as explained above, the temperature gradient across the showerhead 400 is significantly reduced (e.g., to about 30 degrees Celsius with pedestal set points of about 650 degrees Celsius) due to the improved axial cooling provided by the vertical walls 416 in the faceplate 404 that contact the base portion 402, the cooling plate 420, the heater coil 422, and the first and second plates 430, 432. Accordingly, the gap between the faceplate 404 and the pedestal 312 can be further reduced (see FIG. 5). For example, gaps of about 0.2 in., 0.15 in., and 0.11 in. between the showerhead 400 and the pedestal 312 can be achieved while maintaining the radial temperature gradient of about 30 degrees Celsius across the showerhead 400 with pedestal set points of about 650 degrees Celsius without damaging the faceplate 404.

The additional reduction in the gap allows reducing the amount of process gases used during substrate processing, which reduces cost. For example, the amount of process gases used with the showerhead 200 shown in FIG. 2 may about 820 cc whereas that used with the showerhead 400 shown in FIG. 4 may be about 530 cc. Due to the significant reduction in the amount of gases used, gases can be purged and transitioned rapidly, and process cycles (e.g., ALD cycles) can therefore be performed rapidly, which in turn increases throughput (i.e., more number of substrates can be processed in the same amount of time).

The showerhead 400 further comprises an edge ring 442 that helps prevent diffusion of contaminants from the processing chamber back into a micro-volume of process gases in the region between the faceplate 404 and the top of the pedestal 312. Specifically, the bottom surface 439 of the faceplate 404 includes an annular recess 440 along the OD of the faceplate 404. The edge ring 442 is disposed in the annular recess 440. During processing, the diffusion of contaminants into the micro-volume of process gases can be prevented if a velocity at which the process gases flow through a gap 444 between the edge ring 442 and the edge of the pedestal 312 is relatively high regardless of different process gas flows. The relatively high velocity of gas flow through the gap 444 regardless of different process gas flows can be provided as follows.

The gap 444 is defined by two parameters shown in FIG. 5: a distance h (i.e., the height of the gap 444) between the bottom of the edge ring 442 and the top of the ring 343 at the edge of the pedestal 312, and a length L of a passage through the gap 444 (approximately a distance between an ID and an OD of the ring 343 at the edge of the pedestal 312). The velocity at which the process gases flow through the gap 444 is a function of h, L, and a total gas flow used in the process. For example, the smaller the value of h, the higher the velocity of gas flow within the gap 444.

The velocity of gas before entry into the gap 444 scales with the total gas flow used in the process. The value of h needs to be smaller if the velocity of gas before entering the gap 444 is low. Conversely, the value of h can be higher if the velocity of gas before entering the gap 444 is high. Accordingly, to maintain a relatively high velocity within the gap 444, different values of h are needed for different process gas flows. The different values of h can be provided by using the edge ring 442 of a suitable thickness for different processes without changing the distance between the faceplate 404 and the pedestal 312.

FIG. 6 shows the thermal resistor comprising the first and second plates 430, 432 in further detail. The outer diameters of the first and second plates 430 are less than or equal to the OD of the second component 520 of the base portion 402. While not shown, the first and second plates 430, 432 include holes that align with various sets of holes shown in FIGS. 7-9B through which fasteners can be inserted to fasten the cooling plate 420 to the base portion 402.

The first plate 430 includes a plurality of recessed portions 434-1, 434-2, 434-3, . . . , and 434-N, where N is an integer greater than 1 (collectively, the recessed portions 434). The recessed portions 434 can be arranged on at least one of the top and bottom surfaces of the first plate 430. The size, shape, and quantity of the recessed portions 434 on the top surface of the first plate 430 can be such that about 65% of the surface area of the top surface of the first plate 430 is in contact with the bottom surface of the cooling plate 420. Similarly, the size, shape, and quantity of the recessed portions 434 on the bottom surface of the first plate 430 can be such that about 65% of the surface area of the bottom surface of the first plate 430 is in contact with the top surface of the second plate 432. Other percentages may be used for contact areas of the top and bottom surfaces of the first plate 430. For example, the contact areas of the top and bottom surfaces of the first plate 430 may vary between 50-80%. Further, the contact areas of the top and bottom surfaces of the first plate 430 may be different (i.e., unequal).

The first and second plates 430, 432 are made of materials having relatively low thermal conductivities. The first plate 430 may have a higher thermal conductivity than the second plate 432. For example, the thermal conductivities of the first and second plates 430, 432 can be respectively about 15 Watts per meter-Kelvin (W/mK) and 2 W/mK. The first and second plates 430, 432 provide thermal barriers for heat flowing from the faceplate 404 to the cooling plate 420.

The second plate 432 provides a thermal barrier for heat flowing from the faceplate 404 to the first plate 430, and the first plate 430 provides a thermal barrier for heat flowing from the second plate 432 to the cooling plate 420. The first and second plates 430, 432 function as heat chokes or thermal resistors that are in series with each other. Accordingly, the second plate 432 and the first plate 430 present a gradually increasing thermal barrier or thermal resistance to the heat flowing from the faceplate 404 to the cooling plate 420.

The recessed portions 434 include air pockets and are spaced throughout the first plate 430 on at least one of the top and bottom surfaces to further increase the thermal barrier. The stack of the first and second plates 430, 432 forms the thermal resistor that prevents the cooling plate 420 from conducting relatively large amount of heat away from the showerhead 400, which can force the heater coil 422 to operate at a relatively higher capacity. The thermal resistor prevents the coolant (e.g., water) in the conduit 424 from approaching its boiling point due to the heat flow.

Accordingly, the cooling plate 420, the heater coil 422, and the thermal resistor formed by the first and second plates 430, 432 provide a balance between the heating and cooling of the showerhead 400 to minimize the temperature gradient across the showerhead 400 and to keep the temperature of the showerhead 400 below a threshold temperature (e.g., 200 degrees Celsius) to preserve the anticorrosion coating on the showerhead 400.

The first plate 430 may be manufactured as a monolithic plate. Alternatively, the first plate 430 may comprise three layers: two layers (top and bottom layers) including the recessed portions 434 (in the form of recesses or slots that are cut through the layers), and a third layer that is flat (i.e., without the recessed portions 434) and that is sandwiched between the two layers. The three layers may be bonded to each other (e.g., brazed or diffusion bonded).

The recessed portions 434 can be arranged on at least one of the top and bottom surfaces of the first plate 430 in many ways. The recessed portions 434 on the top surface of the first plate 430 may be aligned with the recessed portions 434 on the bottom surface of the first plate 430. Alternatively, the recessed portions 434 on the top surface of the first plate 430 may be offset relative to the recessed portions 434 on the bottom surface of the first plate 430. For example, the recessed portions 434 on the top surface of the first plate 430 may overlap at least one of the recessed portions 434 on the bottom surface of the first plate 430. Alternatively, none of the recessed portions 434 on the top surface of the first plate 430 may overlap the recessed portions 434 on the bottom surface of the first plate 430.

The recessed portions 434 on the top and bottom surfaces of the first plate 430 can have any size, shape, and quantity so long as the contact areas of the top and bottom surfaces of the first plate 430 are as described above. For example, the recessed portions 434 on the top and bottom surfaces of the first plate 430 may be of the same size and shape. Alternatively, the recessed portions 434 on the top surface of the first plate 430 may be of a different size and/or shape than the recessed portions 434 on the bottom surface of the first plate 430. The recessed portions 434 can be arranged on the top and bottom surfaces of the first plate 430 symmetrically or asymmetrically.

The number of the recessed portions 434 can be different (e.g., fewer or more) than that shown. The top and bottom surfaces of the first plate 430 may have the same number of the recessed portions 434. Alternatively, the top surface of the first plate 430 may different number of the recessed portions 434 than the bottom surface of the first plate 430.

The depth of the recessed portions 434 can be the same or can be different. The recessed portions 434 on the top and bottom surfaces of the first plate can have the same depth. Alternatively, the recessed portions 434 on the top surface of the first plate 430 can have a first depth, and the recessed portions 434 on the bottom surface of the first plate 430 can have a second depth. The depths of the recessed portions 434 on the top surface of the first plate 430 can vary in a first pattern, and the depths of the recessed portions 434 on the bottom surface of the first plate 430 can vary in a second pattern. Any combination of the above variations may be used.

The OD's of the first and second plates 430, 432 are less than or equal to the OD of the cooling plate 420 and are less than or equal to the ID of the groove in which the heater coil 422 is disposed in the base portion 402. The thicknesses of the first and second plates 430, 432 can be varied depending on process requirements. The first plate 430 may be thicker than the second plate 432.

In some applications, the second plate 432 may also include recessed portions on at least one of top and bottom surfaces and may include any of the variations described above with reference to the first plate 430. Further, there may be additional permutations and combinations possible between the recessed portions of the first and second plates 430, 432. In some applications, the second plate 432 can be made of a thermoplastic material (e.g., polyimide), can include all of the structural features of the first plate 430 described above, and can be used independently (i.e., by itself instead of being used together with the first plate 430). Alternatively, in some applications, the second plate 432 may be omitted, and the first plate 430 can be made of the thermoplastic material (e.g., polyimide).

Further, while not shown, a third plate having a relatively low thermal conductivity may be used in addition to the first and second plates 430, 432. The third plate may be similar to any of the first and second plates 430, 432 except that the thermal conductivity of the third plate may be different than the first and second plates 430, 432. The third plate may be arranged above, below, or between the first and second plates 430, 432. The thermal conductivity of the third plate may be selected based on the location of the third plate. For example, the third plate arranged below the second plate 432 may have a lower thermal conductivity than the second plate 432. The third plate arranged above the first plate 430 may have a higher thermal conductivity than the first plate 430. The third plate arranged between the first and second plates 430, 432 may have a thermal conductivity less than the first plate 430 and greater than the second plate 432.

FIGS. 7 and 8 respectively show top and bottom views of the showerhead 400. In FIG. 7, a top view of the cooling plate 420 can be seen. The cooling plate 420 is attached to the second component 520 of the base portion 402 by fasteners inserted through holes 431. Holes 409 are provided for inserting fasteners to attach the stem portion 408 to the showerhead 400. Various other sets of mounting/fastening holes 431-1, 431-2, and 431-3 are shown through which fasteners can be inserted to fasten the cooling plate 420 to the base portion 402 through the first and second plates 430, 430.

The top horizontal portion of the clamping ring 564 visible in this view is fastened to the bottom vertical portion of the clamping ring 564 not visible in this view (but visible in FIGS. 4 and 5) by fasteners inserted through holes 433-1. The top horizontal portion of the clamping ring 564 is fastened to the flange 428 of the base portion 402 by fasteners inserted through holes 433-2.

Elements 437-1 and 437-2 are first and second terminals of the heater coil 422 that can be connected to a power supply. Elements 429-1 and 429-2 are respectively inlet and outlet of the conduit 424 that can be connected to a fluid delivery system.

The cooling plate 420 extends radially outwardly from the stem portion 408 (visible in FIG. 5) towards the OD of the base portion 402. The conduit 424 is disposed in corresponding grooves 425 (visible in FIG. 5) in the cooling plate 420. The number of turns of the conduit 424 may be varied (i.e., more or fewer turns than those shown may be used). The diameter of the conduit 424 may be uniform throughout the length of the conduit 424. The size, shape, and layout of the conduit 424 may be optimized to suit process requirements.

Alternatively, the cooling plate 420 may be divided into multiple zones, and a plurality of conduits may be arranged in these zones. For example, a first conduit may be arranged in a first zone comprising an inner half portion of the cooling plate 420, and a second conduit may be arranged in a second zone comprising an outer half portion of the cooling plate 420. As another example, first and second conduits may be arranged in first and second zones defined proximate to the ID and the OD of the cooling plate 420, respectively; and a third conduit may be arranged in a third zone between the first and second zones. Each of the plurality of conduits may be supplied with the same coolant. Alternatively, at least one of the plurality of conduits may be supplied with a different coolant than others of the plurality of conduits. When a plurality of conduits is used, each conduit may have any of the characteristics (size, shape, and layout) described above with reference to the conduit 424.

FIG. 8 shows the bottom view of the showerhead 400 showing the substrate-facing side (i.e., the bottom surface 439) of the faceplate 404. The through holes 427 in the bottom surface 439 of the faceplate 404 are visible in this view. The through holes 427 can also be seen in additional views of the faceplate 404 shown in FIGS. 11A-11B. Also visible in this view is the bottom of the edge ring 442, which is shown and described above in detail with reference to FIGS. 4 and 5.

FIGS. 9A and 9B show the base portion 402 and the faceplate 404 of the showerhead 400 in further detail. FIG. 9A shows an isometric view of the showerhead 400. The first component 500 is not visible in detail in this view (but can be seen in greater detail in FIG. 9B). The second component 520 includes sets of holes 409 and 431-1, 431-2, 431-3 that respectively align with the corresponding sets of holes 409 and 431-1, 431-2, 431-3 shown in FIG. 7. The flange 428 includes holes 433-1 that align with the holes 433-1 shown in FIG. 7.

In FIG. 9B, the first, second, and third components 500, 520, 530 of the base portion 402 are shown in further detail. The first component 500 of the base portion 402 is a first disc-shaped element that includes the groove 411 along the OD of the first component 500. The groove 411 is open at the top surface 560 of the first component 500 and extends vertically downward towards the bottom surface 562 of the first component 500.

The first component 500 includes the slot 502 at the center of the top surface 560 of the first component 500. The slot 502 includes a plurality of grooves 504 extending radially outwards from the center of the slot 502. A plurality of passages 506 extend vertically downwards about halfway through the first component 500 from distal ends of the grooves 504. From about the hallway point, the passages 506 may split (i.e., bifurcate) through the remainder of the first component 500 and may open at the bottom surface 560 of the first component 500 as shown at 507. Accordingly, the passages 506 may have the shape of the inverted letter “Y” as shown at 507 although other shapes are contemplated (e.g., shapes of letters U, V, etc.). The gases received through the inlet 410 pass through the slot 502 and through the passages 506 into the faceplate 404. The first component 500 includes sets of holes 409 and 431-1, 431-2, 431-3 that respectively align with the corresponding sets of holes 409 and 431-1, 431-2, 431-3 of the second component 520 and the respective sets of holes shown in FIG. 7.

The second component 520 of the base portion 402 is a second disc-shaped element. The OD of the second component 520 is less than or equal to the ID of the groove 411 in the first component 500. The second component 520 is arranged on, and is fastened or diffusion bonded to, the top surface 560 of the first component 500. The inlet 410 at the center of the second component 520 aligns with and opens into the slot 502 in the first component 500.

The third component 530 of the base portion 402 is a cylindrical element that is also arranged on, and is fastened or diffusion bonded to, the first component 500. The top end of the third component 530 extends radially outwards to form the flange 428. The ID of the third component 530 is greater than or equal to the OD of the groove 411. A width or thickness of the third component 530 at the bottom end is equal to a distance (or difference) between the OD of the groove 411 and the OD of the second component 520. The OD of the bottom end of the third component 530, the OD of the second component 520, and the OD of the faceplate 404 are equal as can be seen in FIGS. 4 and 5.

The second component 520 is arranged on the first component 500. The third component 530 is also arranged on the first component 500. The third component 530 surrounds the second component 520. The first, second, and third components 500, 520, 530 can be joined together using diffusion bonding to form the base portion 402 of the showerhead 400. Diffusion bonding eliminates fillers typically used when brazing is used to join the components. Eliminating fillers eliminates possibility of contamination due to residual fillers that tend to persist after brazing and subsequent cleaning.

The faceplate 404 includes the vertical walls 416. For example, the vertical walls 416 can be concentric. As described above, the vertical walls 416 can have different heights and/or widths. When the faceplate 404 is attached to the base portion 402, the spaces between the vertical walls 416 and the bottom surface 562 of the first component 500 of the base portion 402 form the plenum 405 in the faceplate 404. The passages 506 in the first component 500 of the base portion 402 open into the plenum 405 in the faceplate 404 (also shown in FIGS. 10A and 10B).

The faceplate 404 includes a plurality of radially extending grooves 540-1, 540-2, 540-3, . . . , and 540-N, where N is an integer greater than 1 (collectively, the grooves 540), which are arranged like spokes of a wheel. The grooves 540 intersect the vertical walls 416 and split the vertical walls 416 into multiple sections. The plurality of through holes 427 (see FIGS. 8 and 11B) are arranged on either sides of the vertical walls 416 on the bottom surface 439 (i.e., the substrate-facing surface, see FIG. 8) of the faceplate 404.

The vertical walls 416 and the through holes 427 are formed within a region of the faceplate 404 that extends from the center of the faceplate 404 up to a predetermined radial distance from the center of the faceplate 404. A corresponding predetermined diameter of the region of the faceplate 404 defined by the predetermined radial distance aligns with (i.e., is less than or equal to) the ID of the recess 440 at the bottom surface 439 of the faceplate 404 in which the edge ring 442 is disposed. Accordingly, the predetermined diameter of the region of the faceplate 404 that includes the vertical walls 416 and the through holes 427 is less than or equal to an ID of the edge ring 442. The predetermined diameter is also less than or equal to the ID of the groove 411 in the base portion 402 as can be seen in FIGS. 4 and 5.

The vertical walls 416 and the grooves 540 uniformly distribute the gases received from the passages 506 in the first component 500 of the base portion 402 to the through holes 427. In addition, as described above with reference to FIGS. 4 and 5, since the vertical walls 416 extend vertically upwards from the faceplate 404 and contact the bottom surface 562 of the base portion 402 (i.e., the bottom surface 562 of the first component 500 of the base portion 402), the vertical walls 416 provide heat paths between the faceplate 404 and the base portion 402.

FIGS. 10A and 10B respectively show isometric and cross-sectional views of the showerhead 400 comprising the base portion 402 and faceplate 404. The inlet 410 of the showerhead 400 receives process gases from a gas distribution system (e.g., element 130 shown in FIG. 1). The process gases flow through the inlet 410, the slot 502, the grooves 504, and the passages 506 into the faceplate 404, and the process gases exit the faceplate 404 via the through holes 427 into the processing chamber. The components of the showerhead 400, particularly the structural and functional details of the base portion 402 and the faceplate 404, have been already described above in detail with reference to FIGS. 4-9B and are therefore not described here again for brevity.

FIGS. 11A and 11B respectively show isometric and top views of a cross-section AA of the faceplate 404 indicated in FIG. 10B. FIGS. 11A and 11B show the vertical walls 416, the grooves 540, and the through holes 427 arranged around the vertical walls 416. As shown, the grooves 540 can be arranged in a pattern. For example, as shown, the grooves 540 may extend radially outwardly from the center of the faceplate 404 all the way up to the predetermined diameter of the faceplate 404 within which the vertical walls 416 and the through holes 427 are arranged.

Alternatively, some of the grooves 540 may extend radially outwardly from the center of the faceplate 404 but may not extend all the way up to the predetermined diameter. In another arrangement, some of the grooves 540 may not begin from the center of the faceplate 404 and may or may not extend radially outwardly all the way up to the predetermined diameter. For example, a first set of the grooves 540 may begin at a first distance from the center of the faceplate 404 and then extend radially outwardly all the way or part of the way up to the predetermined diameter; a second set of the grooves 540 may begin at a second distance from the center of the faceplate 404 and then extend radially outwardly all the way or part of the way up to the predetermined diameter; and so on, where the second distance is different than the first distance.

In other words, the lengths and extents of the grooves 540 in the first set, the second set, and so on may be different (i.e., unequal). Accordingly, some of the vertical walls 416 may be located at the same radial distance from the center of the faceplate 404 but may have different arc-lengths. Other patterns and arrangements of the vertical walls 416 and the grooves 540 that may be suitable for distributing gases received from the inlet 410, the slot 502, the grooves 504, and the passages 506 via the through holes 427 are contemplated.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another are within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A showerhead comprising:
a base portion made of a first metallic material, the base portion having a first surface including a gas inlet and a second surface opposite to the first surface, the base portion including a plurality of passages in fluid communication with the gas inlet;
a faceplate made of a second metallic material, the faceplate having side surfaces attached to the second surface of the base portion and a bottom surface, the side surfaces and the bottom surface of the faceplate and the second surface of the base portion defining a plenum in fluid communication with the plurality of passages, the faceplate including a plurality of walls extending from the bottom surface upwards through the plenum and contacting the second surface of the base portion, and the bottom surface including a plurality of outlets arranged along the walls in fluid communication with the plenum;
a heater disposed in a groove along a periphery of the base portion;
a cooling plate arranged on the first surface of the base portion, the cooling plate including a conduit having an inlet to receive a coolant and an outlet; and
a plate made of a third material having a lower thermal conductivity than the first and second metallic materials arranged between the cooling plate and the base portion of the showerhead.

2. The showerhead of claim 1 wherein outer diameters of the cooling plate and the plate are less than or equal to an inner diameter of the groove.

3. The showerhead of claim 1 wherein:
the walls are vertical and concentric;
the walls have different heights; and
the walls have different widths.

4. The showerhead of claim 1 wherein:
the walls and the outlets are arranged within a region of the faceplate;
outer diameters of the cooling plate and the plate are less than or equal to a diameter of the region; and
the diameter of the region is less than or equal to an inner diameter of the groove.

5. The showerhead of claim 1 wherein the base portion includes a flange extending radially outwards from a top end of the base portion, the showerhead further comprising a clamping ring having a vertical portion arranged on the heater and having a horizontal portion attached to the flange.

6. The showerhead of claim 1 wherein the third material includes a thermoplastic material, the showerhead further comprising an additional plate arranged between the plate and the cooling plate wherein the additional plate has a different thermal conductivity than the third material.

7. The showerhead of claim 6 wherein:
a first outer diameter of the additional plate is greater than or equal to a second outer diameter of the plate; and
the plate is thinner than the additional plate.

8. The showerhead of claim 1 wherein the third material includes a thermoplastic material and wherein the plate comprises:
a first layer including one or more recessed portions;
a second layer that is flat; and
a third layer including one or more recessed portions.

9. The showerhead of claim 8 wherein:
the recessed portions of the first and third layer are aligned with each other;
the recessed portions of the first and third layer partially overlap; or
the recessed portions of the first and third layer do not overlap.

10. The showerhead of claim 1 wherein the base portion comprises:
a first disc-shaped element that includes a groove proximate to an outer diameter of the first disc-shaped element, wherein the heater is arranged in the groove;
a second disc-shaped element arranged on the first disc-shaped element and having an outer diameter that is less than or equal to an inner diameter of the groove; and
a cylindrical element arranged on the first disc-shaped element and having an inner diameter that is greater than or equal to an outer diameter of the groove;
wherein outer diameters of the first and second disc-shaped elements and a bottom portion of the cylindrical element are equal; and
wherein the first and second disc-shaped elements and the cylindrical element are diffusion bonded.

11. The showerhead of claim 10 wherein the first disc-shaped element comprises:
a slot at a center of a top surface of the first disc-shaped element;
wherein the slot is in fluid communication with the gas inlet and includes a plurality of grooves extending radially from the slot; and
wherein the passages extend downward from distal ends of the grooves towards and through a bottom surface of the first disc-shaped element.

12. The showerhead of claim 10 wherein a top end of the cylindrical element includes a flange extending radially outwards, the showerhead further comprising a clamping ring having a vertical portion arranged on the heater and having a horizontal portion attached to the flange.

13. The showerhead of claim 1 wherein:
the faceplate includes a plurality of grooves extending radially outwards from a center of the faceplate;
the grooves are of different lengths;
the walls are vertical and concentric; and
the grooves intersect the walls.

14. A processing chamber comprising the showerhead of claim 1 and a pedestal, wherein:
the faceplate includes an annular recess along an outer diameter of the bottom surface;
the showerhead includes an edge ring disposed in the annular recess;
the edge ring is proximate to an outer edge of a top surface of the pedestal; and
a radially outward gas flow through a gap between the edge ring and the outer edge of the top surface of the pedestal prevents contaminants from the processing chamber from flowing through the gap towards a substrate arranged on the pedestal during substrate processing.

15. A showerhead comprising:
a base portion having a first surface including a gas inlet and a second surface opposite to the first surface, the base portion including a plurality of passages in fluid communication with the gas inlet;
a faceplate having side surfaces attached to the second surface of the base portion and a bottom surface including a plurality of outlets, the faceplate including a plurality of walls extending upwards from the bottom surface upwards and contacting the second surface of the base portion;
a cooling plate arranged on the first surface of the base portion, the cooling plate including a conduit having an inlet to receive a coolant and an outlet; and
a plate having a lower thermal conductivity than the faceplate and the cooling plate arranged between the cooling plate and the base portion of the showerhead.

16. The showerhead of claim 15 wherein the plate is made of a thermoplastic material and wherein the plate comprises:
a first layer including one or more recessed portions;
a second layer that is flat; and
a third layer including one or more recessed portions.

17. The showerhead of claim 15 wherein the base portion comprises:
a first disc-shaped element that includes a heater arranged in a groove proximate to an outer diameter of the first disc-shaped element;
a second disc-shaped element arranged on the first disc-shaped element and having an outer diameter that is less than or equal to an inner diameter of the groove; and
a cylindrical element arranged on the first disc-shaped element and has an inner diameter that is greater than or equal to an outer diameter of the groove; and
wherein outer diameters of a bottom portion of the cylindrical element and the first and second disc-shaped elements are equal.

18. The showerhead of claim 17 wherein the first disc-shaped element comprises a slot at a center of a top surface of the first disc-shaped element, the slot being in fluid communication with the gas inlet and including a plurality of grooves extending radially from the slot, wherein the passages extend downward from distal ends of the grooves towards and through a bottom surface of the first disc-shaped element.

19. The showerhead of claim 17 wherein a top end of the cylindrical element includes a flange extending radially outwards, the showerhead further comprising a clamping ring having a vertical portion arranged on the heater and having a horizontal portion attached to the flange.

20. The showerhead of claim 15 wherein the faceplate includes:
a plurality of grooves extending radially outwards from a center of the faceplate, the grooves being of different lengths, the walls being vertical and concentric, and the grooves intersecting the walls; and
an annular recess along an outer diameter of the bottom surface, the annular recess including an edge ring allowing a radially outward gas flow through a gap between the edge ring and an outer edge of a top surface of a pedestal.
